(19) United States
(12) Patent Application Publication
(10) Pub. No.: US 2026/0068609 A1
(43) Pub. Date: Mar. 5, 2026

(54) SEMICONDUCTOR DEVICE AND SEMICONDUCTOR MODULE

(71) Applicant: FUJI ELECTRIC CO., LTD., Kanagawa (JP)

(72) Inventor: Koki HIROHATA, Matsumoto-city (JP)

(21) Appl. No.: 19/245,378

(22) Filed: Jun. 22, 2025

(30) Foreign Application Priority Data
Aug. 27, 2024 (JP) 2024-145927

(51) Int. Cl. H01L 21/66; H01L 23/00

(52) U.S. Cl. CPC H01L 22/30

(57) ABSTRACT

Provided is a semiconductor device, including: a protective film provided above a front surface of a semiconductor substrate; and a front surface electrode provided above the front surface of the semiconductor substrate; where the front surface electrode includes: a plurality of bonding regions exposed through a plurality of opening portions provided in the protective film; and a plurality of testing regions for testing, and where in a top view of the semiconductor substrate, an area of each testing region is smaller than an area of each bonding region. Furthermore, provided is a semiconductor module including a semiconductor device.

The contents of the following patent application(s) are incorporated herein by reference: NO. 2024-145927 filed in JP on Aug. 27, 2024.

### BACKGROUND

### 1. Technical Field

The present invention relates to a semiconductor device and a semiconductor module.

### 2. Related Art

Patent Document 1 discloses that the dual direction switching device 100 includes first transistor regions 101a, 101b and 101c and second transistor regions 102a, 102b and 102c, and includes first source electrode pads 161a and 161b and second source electrode pads 162a and 162b corresponding to each of the transistor regions outside the source electrodes 20a to 20d.

### PRIOR ART DOCUMENTS

### Patent Document

Patent Document 1: Japanese Patent Application Publication No. 2019-169492

### BRIEF DESCRIPTION OF THE DRAWINGS

FIG. 1 shows an example of an arrangement of each component on a front surface of a semiconductor device 100 according to the example.

FIG. 2 shows an example of an arrangement of an emitter electrode 52 provided on the front surface of the semiconductor device 100.

FIG. 3 shows an example of an arrangement of a protective film 150 provided on the front surface of the semiconductor device 100.

FIG. 4 shows an example of a top plan view of the semiconductor device 100.

FIG. 5 shows an example of an a-a′ cross section of FIG. 4.

FIG. 6 is a top plan view showing an example of a semiconductor module 300 according to the example.

FIG. 7 shows an example of a b-b′ cross section of FIG. 6.

FIG. 8 shows an example of a top plan view of the semiconductor device 100.

FIG. 9 shows another example of a top plan view of the semiconductor device 100.

FIG. 10 shows an example of an arrangement of a protective film 1150 provided on a semiconductor device 1100 according to the comparative example.

FIG. 11 shows an example of a top plan view of a semiconductor module 1300 according to the comparative example.

FIG. 12 is a cross section analysis diagram of the semiconductor module 1300 when a crack occurs in the bonding wire and the sealing resin.

FIG. 13 shows a Focused Ion Beam analysis (FIB-SEM) image in which a region (1) on a c-c′ cross section of FIG. 12 is enlarged.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention.

As used herein, one side in a direction parallel to a depth direction of a semiconductor substrate is referred to as “upper” and another side is referred to as “lower”. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It should be noted that the +Z axis direction and the −Z axis direction are directions opposed to each other. If the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as a depth direction. In addition, in the present specification, a direction parallel to the front surface and the back surface of the semiconductor substrate may be referred to as a horizontal direction, including an X axis direction and a Y axis direction.

A region from the center in a depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

A case where a term such as “same” or “equal” is used in the present specification may include a case where an error due to a variation in manufacturing or the like is included. The error is, for example, within 10%.

In the present specification, a conductivity type of a doping region doped with impurities is described as a P type or an N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

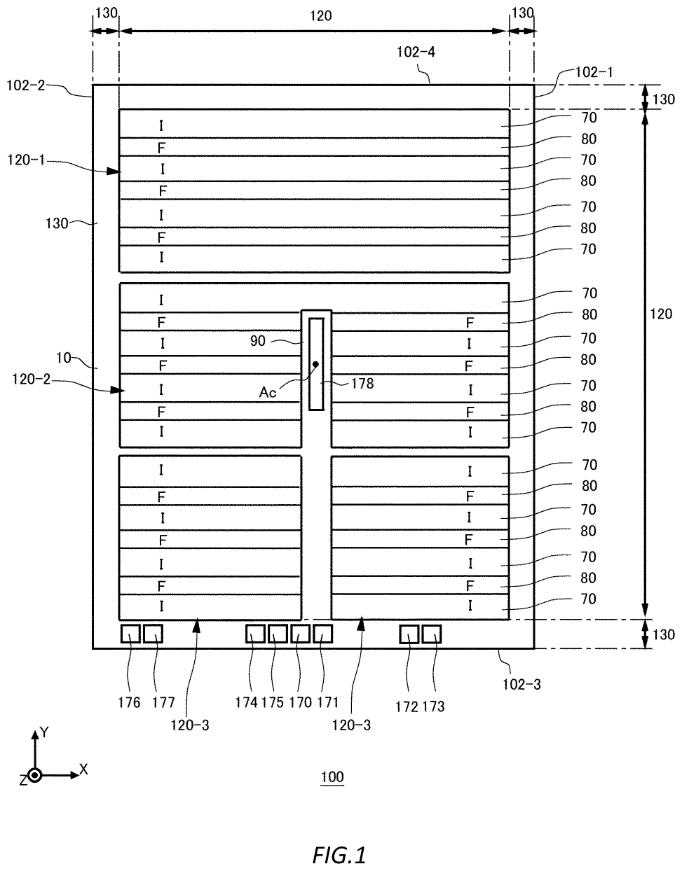

FIG. 1 shows an example of an arrangement of each component on a front surface of a semiconductor device 100 according to the example. The semiconductor device 100 includes a semiconductor substrate 10, a gate pad 170 and a testing pad 171 thereof, a current sensing pad 172 and a testing pad 173 thereof, a temperature sensing portion 178, and an anode pad 174 and a cathode pad 176 electrically connected to a temperature sensing portion 178 and the respective testing pads 175 and 177. A region provided with the gate pad 170 and the testing pad 171 thereof, the current sensing pad 172 and the testing pad 173 thereof, the anode pad 174 and the testing pad 175 thereof, and the cathode pad 176 and the testing pad 177 thereof may collectively be referred to as a pad region. The pad region of the present example may be provided between an active portion 120 described below and an end side 102-3.

The semiconductor substrate 10 has an end side 102. The end side 102 of the present example may include an end side 102-1, an end side 102-2, an end side 102-3, and an end side 102-4. As used herein, in a top view of FIG. 1, a direction along one end side 102-3 of the semiconductor substrate 10 is considered to be an X axis direction, and a direction perpendicular to the X axis direction is considered to be a Y axis direction. In the present example, the X axis is taken in a direction of the end side 102-3 and the end side 102-4, while the Y axis is taken in a direction of the end side 102-1 and the end side 102-2. The Y axis of the present example may be a longitudinal direction of the semiconductor substrate 10. A direction being perpendicular to the X axis direction and the Y axis direction, and forming a right-hand system with the X axis direction and the Y axis direction is referred to as a Z axis direction. The temperature sensing portion 178 of the present example is provided in the +Z axis direction of the semiconductor substrate 10.

The semiconductor substrate 10 is provided of a semiconductor material such as silicon or a compound semiconductor. A side of the semiconductor substrate 10 on which the temperature sensing portion 178 is provided is referred to as a front surface, and the opposing side is referred to as a back surface. As used herein, a direction connecting the front surface and the back surface of the semiconductor substrate 10 is referred to as a depth direction. Although the semiconductor substrate 10 of the present example has a substantially rectangular shape on the front surface, it may be in a different shape.

The semiconductor substrate 10 includes an active portion 120. The active portion 120 is a region in which a main current flows in the depth direction between the front surface and the back surface of the semiconductor substrate 10 when the semiconductor device 100 is turned on. A gate conductive portion 44 of the active portion 120 which will be described below is electrically connected to the gate pad 170 through a gate wiring portion which will be described below.

The active portion 120 may be arranged to be divided into an active portion 120-1, an active portion 120-2, and an active portion 120-3, in a top view. In the present example, from the positive side to the negative side of the Y axis direction, the active portion 120-1, the active portion 120-2, and the active portion 120-3 are arranged in this order.

The active portion 120-1 of the present example is provided to extend between the end side 102-1 and the end side 102-2 in the X axis direction. The active portion 120-2 and the active portion 120-3 of the present example are separated in the X axis direction by a separating portion 90 extending from a location in the vicinity of the center Ac of the front surface of the semiconductor substrate 10 to the negative side in the Y axis direction. In other words, the separating portion 90 may be a region in which the active portion 120 is not provided. Here, the center Ac is the geometric gravity center of the active portion 120 in a top view. The active portion 120-2 may extend in part in the X axis direction and be separated in part in the X axis direction by the separating portion 90. The active portion 120-2 may be provided with a temperature sensing portion 178 described below interposed therebetween.

The active portion 120 of the present example is provided with a transistor portion 70 including a transistor device such as an IGBT (insulated gate bipolar transistor) and a diode portion 80 including a diode device such as an FWD (free wheeling diode). The transistor portion 70 and the diode portion 80 form an RC-IGBT (Reverse Conducting IGBT).

In FIG. 1, in the active portion 120, a region in which the transistor portion 70 is arranged is provided with a symbol “I” and a region in which the diode portion 80 is arranged is provided with a symbol “F”. The transistor portion 70 and the diode portion 80 of the present example extend in the X axis direction and are alternately arranged next to each other in the Y axis direction in each region of the active portion 120. Note that the active portion 120 of the present example may be an IGBT or may be an MOSFET (Metal-Oxide-Semiconductor Field Effect Transistor).

The semiconductor device 100 includes an edge termination structure 130 between an outer circumference of the active portion 120 and the end side 102 on the front surface. The edge termination structure 130 includes, for example, a guard ring, a field plate, and a structure of a combination thereof which are annularly provided so as to surround the active portion 120.

The temperature sensing portion 178 may be arranged in the separating portion 90. The separating portion 90 is not provided with the active portion 120. In the semiconductor device 100, a location around the center Ac on the front surface of the semiconductor substrate 10 tends to be heated due to a heat generated by a switching device formed in the active portion 120. The temperature sensing portion 178 is provided in the separating portion 90 including the center Ac so that a temperature of the transistor portion 70 can be monitored. This can prevent the transistor portion 70 from overheating beyond a bonding temperature that is a normal operating temperature range.

The temperature sensing portion 178 may be formed of a temperature sensing diode. The temperature sensing portion 178 may be provided by PN junction diodes of polysilicon provided via a dielectric film above the semiconductor substrate 10.

The anode pad 174 is connected to the temperature sensing portion 178 via the anode wiring 182. The cathode pad 176 is connected to the temperature sensing portion 178 via the cathode wiring 180. The cathode pad 176 and the anode pad 174 are electrodes containing metal such as aluminum. An anode and a cathode of the temperature sensing diode are connected to the anode pad 174 and the cathode pad 176 via the anode wiring and the cathode wiring formed of metal, respectively.

The current sensing pad 172 is electrically connected to a current sensing portion. The current sensing pad 172 is one example of the front surface electrode. The current sensing portion has a structure similar to the structure of the transistor portion 70 in the active portion 120, and simulates operations of the transistor portion 70. A current that flows into the current sensing portion is in proportion to a current that flows into the transistor portion 70. This enables to monitor a current flowing in the transistor portion 70.

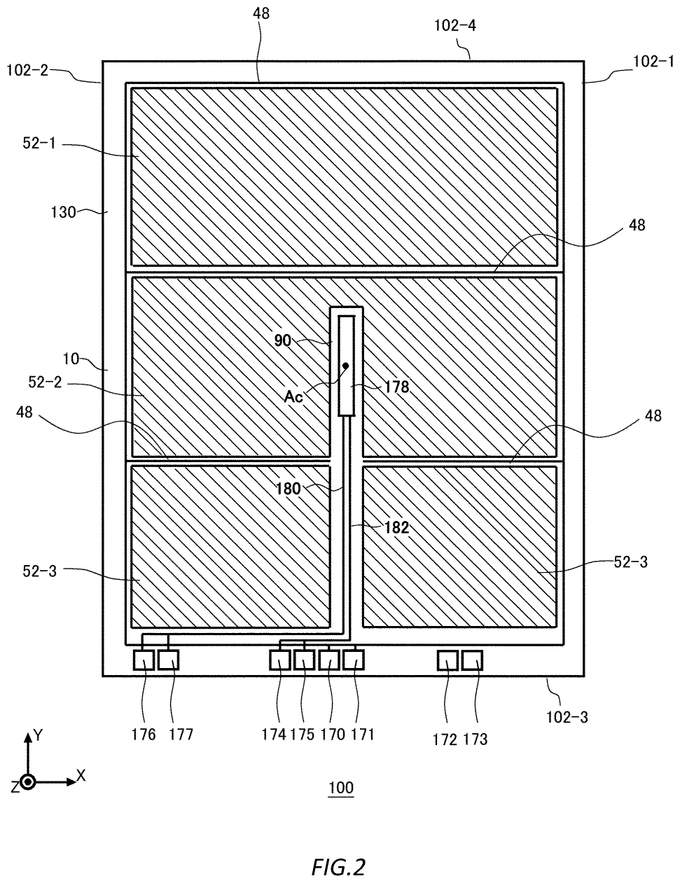

FIG. 2 shows an example of an arrangement of an emitter electrode 52 provided on the front surface of the semiconductor device 100. FIG. 2 further shows the gate runner portion 48, the anode wiring 182 and the cathode wiring 180 as an example of a wiring connected to the pad region. The emitter electrode 52 is provided with a conductor of a metal such as aluminum. The emitter electrode 52 of the present example is set to be an emitter potential which is a predetermined reference potential. Alternatively, the emitter potential may be set to a ground potential.

The emitter electrode 52 is formed of a conductive material including a metal. For example, the emitter electrode 52 is formed aluminum or an alloy including aluminum as a main component (an alloy of aluminum-silicon, aluminum-silicon-copper, or the like). The emitter electrode 52 is an example of a front surface electrode, similarly to the current sensing pad 172. Each electrode may have, in an under layer of the region formed of aluminum or the like, a barrier metal which is formed of titanium, titanium compounds, or the like.

In FIG. 2, the emitter electrode 52 is arranged in a region hatched with diagonal lines. The emitter electrode 52 may be arranged to be divided into an emitter electrode 52-1, an emitter electrode 52-2, and an emitter electrode 52-3 in a top view. The emitter electrode 52-1, the emitter electrode 52-2 and the emitter electrode 52-3 of the present example are provided to correspond to the active portion 120-1, the active portion 120-2, and the active portion 120-3, respectively. The emitter electrode 52 is not provided above the separating portion 90 separating at least a portion of the active portion 120-2 in the Y axis direction. Similarly, the emitter electrode 52 is not provided above the pad region.

The gate runner portion 48 of the present example may be arranged to surround the active portion 120 in a top view of the semiconductor substrate 10. The gate runner portion 48 of the present example may include a branch extending between the emitter electrodes 52 in the X axis direction. The X axis direction is an example of a second direction. The gate runner portion 48 may be a wiring formed of a conductive material such as polysilicon doped with impurities or metal. Furthermore, the gate runner portion 48 may be a wiring of polysilicon doped with impurities and may be electrically connected to a conductive material such as a metal through a contact hole formed in an interlayer dielectric film provided on the upper surface thereof. The gate runner portion 48 supplies a gate voltage applied to the gate pad 170 to the transistor portion 70. The gate runner portion 48 may be arranged above a well region 17 which will be described below.

While the emitter electrode 52 of the present example is provided in a range not overlapped with the gate runner portion 48, it may be overlapped with the gate runner portion 48. In this case, a dielectric film is provided between the emitter electrode 52 and the gate runner portion 48. An interlayer dielectric film is provided between the emitter electrode 52 and the front surface of the semiconductor substrate 10, which is omitted in FIG. 2. The gate runner portion 48 is connected to a gate conductive portion in a gate trench portion of the transistor portion 70 on the front surface of the semiconductor substrate 10.

The anode wiring 182 and the cathode wiring 180 of the present example may be provided to extend through the separating portion 90 from the temperature sensing portion 178. The anode wiring 182 and the cathode wiring 180 are connected to an anode and a cathode of the temperature sensing portion 178, respectively. The anode wiring 182 and the cathode wiring 180 may be a wiring including a metal such as aluminum. The anode wiring 182 and the cathode wiring 180 are an example of a temperature sensing wire.

The cathode pad 176 of the present example is connected to the temperature sensing portion 178 via the cathode wiring 180.

The anode pad 174 of the present example is connected to the temperature sensing portion 178 via the anode wiring 182.

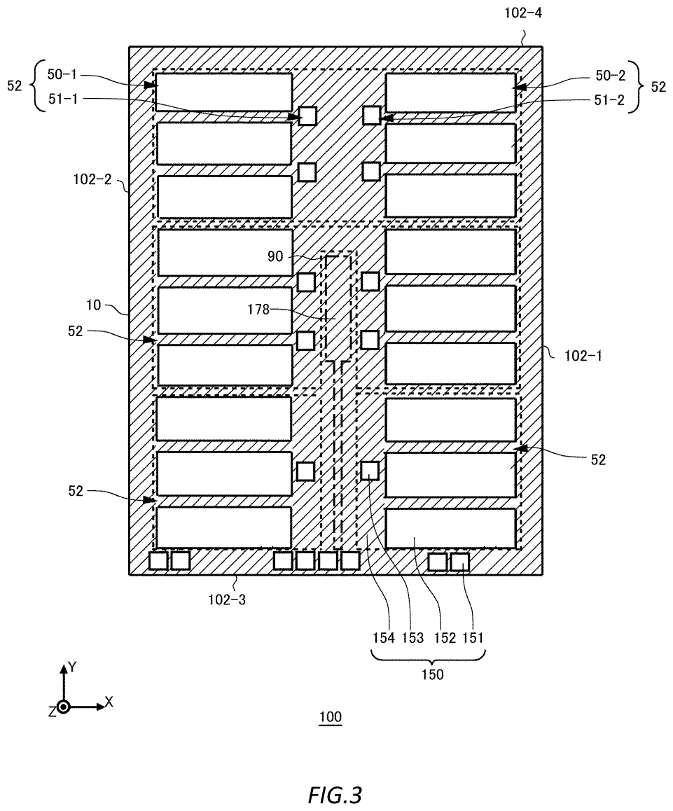

FIG. 3 shows an example of an arrangement of a protective film 150 provided above the front surface of the semiconductor device 100. The protective film 150 of the present example is formed of polyimide. FIG. 3 shows a contour of a region in which the protective film 150 is arranged indicated by solid lines and hatched with diagonal lines. Furthermore, FIG. 3 shows a contour of a region in which the emitter electrode 52 is arranged indicated by dashed lines and shows a contour of a region in which the temperature sensing portion 178 and the temperature sensing wire are arranged in the separating portion 90 indicated by dash-dotted lines. The protective film 150 may be in contact with an upper surface of the emitter electrode 52.

The protective film 150 of the present example may include an opening portion 151 exposing a part of an upper surface of a pad in the pad region, an opening portion 152 and an opening portion 153 exposing a part of an upper surface of the emitter electrode 52, and a not-opening portion 154. The protective film 150 of the present example is provided with a plurality of opening portions 151. The plurality of opening portions 151 enable a wire or the like to be connected on the upper surfaces of the gate pad 170, the current sensing pad 172, the anode pad 174 and the cathode pad 176.

The protective film 150 of the present example is provided with a plurality of opening portions 152 and a plurality of opening portions 153. The emitter electrode 52 includes a plurality of bonding regions 50 and a plurality of testing regions 51 exposed by the plurality of opening portions 152 and the plurality of opening portions 153, respectively. The bonding region 50 may be used as a region for which a bonding wire is bonded in the semiconductor module. The testing region 51 may be used as a region for a probe or the like are connected in the wafer test.

The plurality of opening portions 152 may be arrayed in matrix in a top view of the semiconductor substrate 10. In the present example, two lines of the opening portions 152 arrayed in the Y axis direction are opposed to each other in the X axis direction around the separating portion 90 as a center, the plurality of bonding regions 50 include a group of the first bonding regions 50-1 and a group of the second bonding regions 50-2 arrayed in the Y axis direction, and these groups are opposed to each other in the X axis direction around the separating portion 90 as a center.

The Y axis direction is an example of a predetermined first direction and may be a longitudinal direction of the semiconductor substrate 10. FIG. 3 shows a bonding region 50 provided in the negative side in the X axis direction as compared to the separating portion 90 as a first bonding region 50-1, and a bonding region 50 provided in the positive side in the X axis direction as compared to the separating portion 90 as a second bonding region 50-2.

The plurality of opening portions 153 may be arranged in the center portion of the semiconductor substrate 10 along the Y axis direction in a top view of the semiconductor substrate 10. The number of the plurality of opening portions 153 may be smaller than the number of the plurality of opening portions 152. The plurality of testing regions 51 may be provided in the center portion of the semiconductor substrate 10 along the Y axis direction in a top view of the semiconductor substrate 10. Here, the center portion of the semiconductor substrate 10 refers to the separating portion 90 and an extending range of the separating portion 90 in the Y axis direction. That is, the center portion of the semiconductor substrate 10 refers to the center of the semiconductor substrate 10 in the X axis direction and locations in the vicinity of the center in a top view of the semiconductor substrate 10. The plurality of testing regions 51 of the present example are arrayed between the group of the first bonding regions 50-1 and the group of the second bonding regions 50-2 arrayed in the Y axis direction in a top view of the semiconductor substrate 10.

In the present example, the two lines of the opening portions 153 are arrayed in the Y axis direction, and the plurality of testing regions 51 include a group of the first testing regions 51-1 and a group of the second testing regions 51-2 arrayed in the Y axis direction. In an example, each of the group of the first testing regions 51-1 and the group of the second testing regions 51-2 includes five first testing regions 51. FIG. 3 shows the testing region 51 provided in the negative side in the X axis direction as compared to the temperature sensing portion 178 as a first testing region 51-1, and the testing region 51 provided in the positive side in the X axis direction as compared to the temperature sensing portion 178 as a second testing region 51-2. The testing region 51 of the present example is not provided in the vicinity of the gate runner portion 48.

The temperature sensing portion 178 of the present example may be provided between the group of the first testing regions 51-1 and the group of the second testing regions 51-2 in a top view of the semiconductor substrate 10. The temperature sensing portion 178 of the present example may be provided between the plurality of testing regions 51 in a top view of the semiconductor substrate 10. That is, the temperature sensing portion 178 may be arranged to be interposed between any two testing regions 51 among the plurality of testing regions 51 in a top view of the semiconductor substrate 10.

In a top view of the semiconductor substrate 10, an area of each testing region 51 is smaller than an area of each bonding region 50. The length of each side of the testing region 51 may be smaller than the length of each side of the bonding region 50. In the longitudinal direction of the semiconductor substrate 10, the width of the testing region 51 may be smaller than the width of the bonding region 50. In the short direction of the semiconductor substrate 10, the width of the testing region 51 may be smaller than the width of the bonding region 50. In a top view of the semiconductor substrate 10, an area of each testing region 51 may be 5% to 20% of an area of each bonding region 50.

In the conventional wafer test, a probe or the like is connected to a bonding region of the emitter electrode to measure a wiring resistance or the like. However, a sealing resin of the semiconductor module may be detached from an upper surface of the emitter electrode when a reliability test of the semiconductor module is performed under the high temperature condition, for example. An imprint of the probe formed in the wafer test remains on the upper surface of the emitter electrode, which may further cause a detachment of the sealing resin of the semiconductor module.

In the semiconductor device 100 of the present example, the emitter electrode 52 includes the testing region 51 provided separately aside from the bonding region 50, where an area of the testing region 51 is smaller than an area of the bonding region 50. Therefore, in the bonding region 50, the sealing resin of the semiconductor module can be prevented from being detached from the upper surface of the emitter electrode.

The not-opening portion 154 is a region other than the opening portion in the protective film 150. The not-opening portion 154 of the present example may be provided between the group of the first bonding regions 50-1 and the group of the second bonding regions 50-2. The not-opening portion 154 of the present example may be provided above the gate runner portion 48, the temperature sensing portion 178, the anode wiring 182, and the cathode wiring 180. At least a portion of the not-opening portion 154 of the present example may be provided above the emitter electrode 52.

A sealing resin of the semiconductor module may be detached from an upper surface of the emitter electrode when a reliability test of the semiconductor module is performed under the high temperature condition, for example. Here, it is known that a detachment of the sealing resin of the semiconductor module tends to occur in the peripheral region. On the other hand, the polyimide protective film 150 has a higher adhesion to the sealing resin of the semiconductor module than that of the emitter electrode 52 formed of aluminum or an alloy including aluminum as a main component.

The pad region of the present example is provided between the active portion 120-3 and the end side 102-3. The region between the active portion 120-3 and the end side 102-3 is covered by the not-opening portion 154, other than the pad region exposed by the plurality of opening portions 151. In the semiconductor device 100 of the present example, the testing region 51 is provided in the center portion of the semiconductor substrate 10, but not provided in the pad region. Therefore, an opening portion ratio is not increased in the peripheral region. This prevents a decrease in an area ratio where the sealing resin contacts the polyimide in the peripheral region of the semiconductor module 300 so that the sealing resin of the semiconductor module can be prevented from being detached.

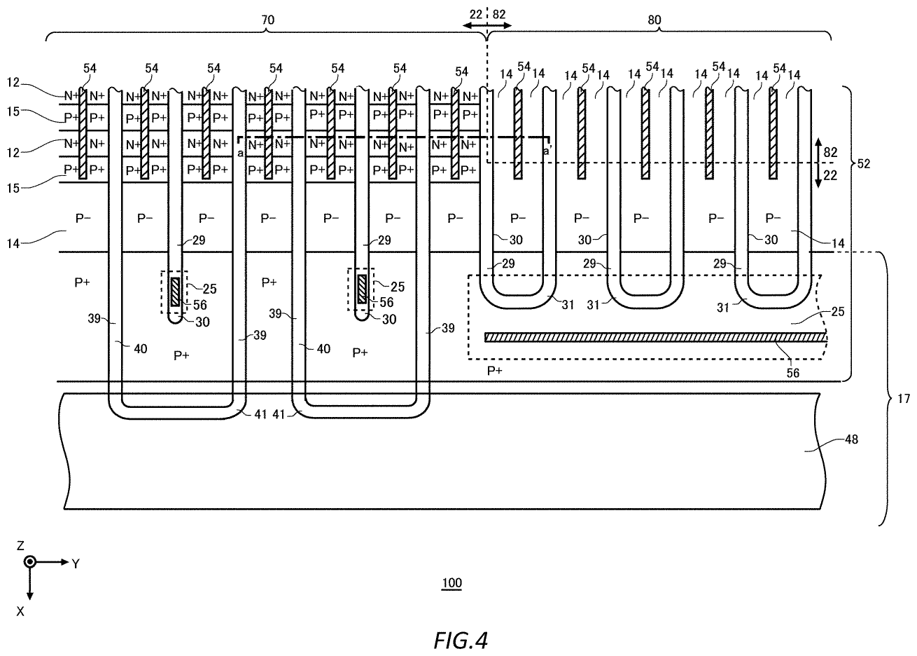

FIG. 4 shows an example of a top plan view of the semiconductor device 100. FIG. 4 shows a location in the vicinity of the end portion of the active portion 120-1 in the positive side in the X axis direction. The semiconductor device 100 of the present example includes the semiconductor substrate 10 including the transistor portion 70 including a transistor device such as an IGBT and the diode portion 80 including a diode device such as a free wheeling diode (FWD).

The semiconductor device 100 of the present example includes a gate trench portion 40, a dummy trench portion 30, a well region 17, an emitter region 12, a base region 14, and a contact region 15 provided inside the front surface side of the semiconductor substrate 10. Each of the gate trench portion 40 and the dummy trench portion 30 is an example of the trench portion.

The emitter electrode 52 is provided above the front surface of the semiconductor substrate 10. The emitter electrode 52 is an example of a front surface electrode. FIG. 4 illustrates a range where the emitter electrode 52 is provided. An interlayer dielectric film is provided between the emitter electrode 52 and the front surface of the semiconductor substrate 10, which is omitted in FIG. 4. The interlayer dielectric film of the present example is provided with contact holes 54 and 56 penetrating the interlayer dielectric film. In FIG. 4, each contact hole is hatched with the diagonal lines.

The emitter electrode 52 is provided above the gate trench portion 40, the dummy trench portion 30, the well region 17, the emitter region 12, the base region 14, and the contact region 15. The emitter electrode 52 is electrically connected to the emitter region 12, the base region 14 and the contact region 15 on the front surface of the semiconductor substrate 10 through the contact hole 54. In addition, the emitter electrode 52 is connected to a dummy conductive portion in the dummy trench portion 30 through the contact hole 56.

Connection portions 25 which are formed of conductive material such as polysilicon or the like doped with impurities may be provided between the emitter electrode 52 and the dummy conductive portions. The connection portion 25 is provided above the front surface of the semiconductor substrate 10. A dielectric film is provided between the connection portion 25 and the front surface of the semiconductor substrate 10.

The emitter electrode 52 may have a barrier metal formed of titanium, a titanium compound, or the like in an under layer of a region formed of aluminum or the like. The emitter electrode 52 may have a plug formed of tungsten or the like in the contact hole. The plug may include a barrier metal on the side in contact with the semiconductor substrate 10 and be formed by filling tungsten to be in contact with the barrier metal.

The plug of the present example is provided in the contact hole 54 in contact with the contact region 15 or the base region 14. In addition, a plug region of the P++ type having a higher doping concentration than that of the contact region 15 may be provided below the contact hole 54 provided with the plug. This improves a contact resistance between the barrier metal and the contact region 15. The plug region improves the contact resistance such that the latch-up withstand capacity can increase during an operation of the transistor portion 70 and an increase in a conduction loss or a switching loss can be prevented during an operation of the diode portion 80.

Each of the transistor portion 70 and the diode portion 80 has a plurality of trench portions arrayed in an array direction. In the transistor portion 70 of the present example, one or more gate trench portions 40 and one or more dummy trench portions 30 are alternately provided along the array direction. In the diode portion 80 in this example, the plurality of dummy trench portions 30 are provided along the array direction.

In the present example, the array direction of the trench portion is the Y axis direction and the extending direction perpendicular to the array direction is the X axis direction. The gate trench portion 40 of the present example may have two extending portions 39 extending along the extending direction (a straight portion of the trench along the extending direction), and a connecting portion 41 connecting the two extending portions 39.

At least a portion of the connecting portion 41 may be provided in a curved shape in a top view. The end portions of the two extending portions 39 in the Y axis direction are connected to the gate runner portion 48 via the connecting portion 41. The connecting portion 41 has a curved shape so that an electric field strength at the end portions can be reduced as compared to the trench portion terminates with the extending portion 39.

In the transistor portion 70, the dummy trench portion 30 is provided between the respective extending portions 39 of the gate trench portions 40. In the example of FIG. 4, one dummy trench portion 30 is provided between the respective extending portions 39. However, two or more dummy trench portions 30 may be provided.

In addition, between the respective extending portions 39, the dummy trench portion 30 may not be provided, or the gate trench portion 40 may be provided. With such a structure, the electron current from the emitter region 12 can be increased, so that an ON voltage is reduced.

The dummy trench portion 30 may have a straight shape extending in the extending direction, and may have an extending portion 29 and a connecting portion 31, similarly to the gate trench portion 40. In the diode portion 80 shown in FIG. 4, only the dummy trench portion 30 including the connecting portion 31 is arrayed. However, in another example, the diode portion 80 may include the dummy trench portion 30 of a straight shape which does not include the connecting portion 31.

A dielectric film is provided between the gate runner portion 48 and the front surface of the semiconductor substrate 10. The gate runner portion 48 is connected to a gate conductive portion in the gate trench portion 40 on the front surface of the semiconductor substrate 10. The gate runner portion 48 is not connected to a dummy conductive portion in the dummy trench portion 30.

The well region 17 is provided to be closer to the front surface side of the semiconductor substrate 10 than the drift region 18 which will be described below. The well region 17 of the present example is of the P+ type. The well region 17 of the present example is provided in the edge termination structure 130 and the separating portion 90. In addition, the well region 17 is provided in a predetermined range from the outer circumferences to the inner sides of the active portion 120-1, the active portion 120-2 and the active portion 120-3. The well region 17 is electrically connected to the emitter electrode 52. The well region 17 is provided from the front surface of the semiconductor substrate 10 to a position deeper than the lower end of the base region 14.

A diffusion depth of the well region 17 may be deeper than depths of the gate trench portion 40 and the dummy trench portion 30. The end portions in the X axis direction of the gate trench portion 40 and the dummy trench portion 30 are provided in the well region 17 in a top view. That is, at an end portion of each trench portion in the X axis direction, a bottom portion of each trench portion in the depth direction (the −Z axis direction) is covered by the well region 17. With this configuration, the electric field strength on the bottom portion of each trench portion can be reduced.

A mesa portion between the trench portions adjacent to each other in the array direction is provided. The mesa portion refers to a region sandwiched between the trench portions inside the semiconductor substrate 10. As an example, a depth position of the mesa portion is from the front surface of the semiconductor substrate to a lower end of the trench portion.

The mesa portion of the present example is interposed between the adjacent trench portions in the Y axis direction, and provided to extend in the X axis direction along the trench on the front surface of the semiconductor substrate 10.

Each mesa portion is provided with the base region 14. Each mesa portion may be provided with at least one of the emitter region 12 and the contact region 15 in a region interposed between the base regions 14 in a top view. The base region 14 of the present example is of the P− type, the emitter region 12 is of the N+ type, and the contact region 15 is of the P+ type. The base region 14 is provided in contact with the well region 17. The emitter region 12 and the contact region 15 may be provided between the base region 14 and the front surface of the semiconductor substrate 10 in the depth direction. Examples of the dopant of the emitter region 12 include arsenic (As), phosphorus (P), antimony (Sb), and the like.

The mesa portion of the transistor portion 70 has the emitter region 12 exposed to the front surface of the semiconductor substrate 10. The emitter region 12 is provided in contact with the gate trench portion 40. The mesa portion in contact with the gate trench portion 40 is provided with the contact region 15 exposed to the front surface of the semiconductor substrate 10.

Each of the contact region 15 and the emitter region 12 in the mesa portion is provided from one trench portion to the other trench portion in the Y axis direction. As an example, the contact region 15 and the emitter region 12 in the mesa portion are alternately arranged along the extending direction of the trench portion (the X axis direction).

In another example, the contact region 15 and the emitter region 12 in the mesa portion may be provided in a stripe shape along the extending direction of the trench portion (the X axis direction). For example, the emitter region 12 is provided in a region in contact with the trench portion, and the contact region 15 is provided in a region sandwiched between the emitter regions 12.

The emitter region 12 is not provided in the mesa portion of the diode portion 80. An upper surface of the mesa portion of the diode portion 80 may be provided with the base region 14. The base region 14 may be arranged in the entire mesa portion of the diode portion 80. The base region 14 of the diode portion 80 operates as an anode.

The contact hole 54 is provided above each mesa portion. The contact hole 54 is arranged in a region interposed between the base regions 14 in the extending direction thereof (the X axis direction). The contact hole 54 of the present example is provided above respective regions of the contact region 15, the base region 14, and the emitter region 12. The contact hole 54 may be arranged at the center of the mesa portion in the array direction (the Y axis direction).

In the diode portion 80, a back surface of the semiconductor substrate 10 is provided with a cathode region 82 of the N+ type. In the back surface of the semiconductor substrate, a region in which the cathode region 82 is not provided may be provided with a collector region 22 of a P+ type. In FIG. 4, a boundary between the cathode region 82 and the collector region 22 is indicated by a dashed line.

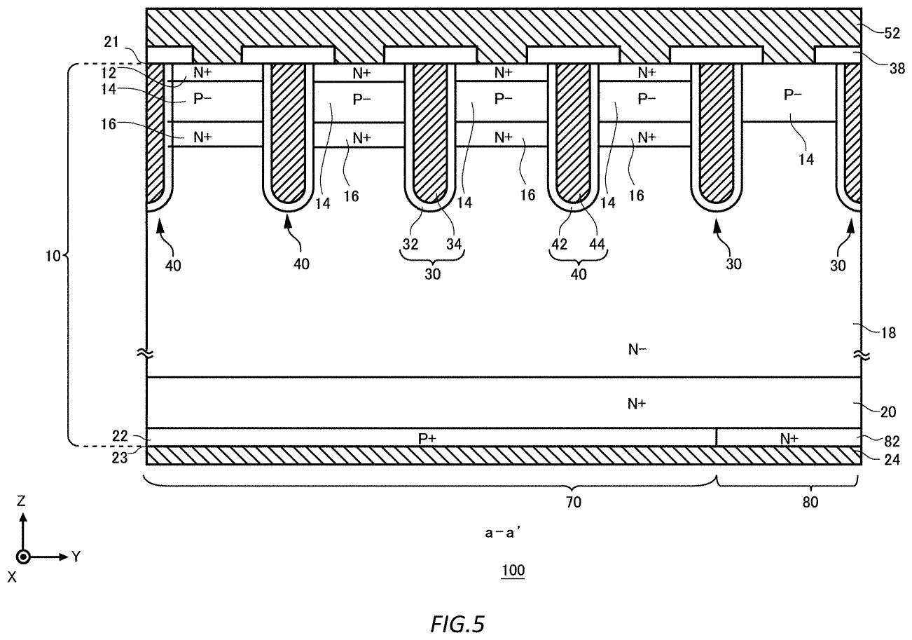

FIG. 5 shows an example of an a-a′ cross section of FIG. 4. The a-a′ cross section is a YZ plane passing through a part of the transistor portion 70 and the diode portion 80 and passing through the emitter region 12 in the transistor portion 70.

The semiconductor device 100 of the present example has the semiconductor substrate 10, the interlayer dielectric film 38, the emitter electrode 52 and the collector electrode 24 on the a-a′ cross section. The interlayer dielectric film 38 is provided above the front surface 21 of the semiconductor substrate 10 and the emitter electrode 52 is provided above the interlayer dielectric film 38. The protective film 150 is provided above the emitter electrode 52, which is omitted in FIG. 5, however.

The drift region 18 is a region provided in the semiconductor substrate 10. The drift region 18 in the present example is of the N-type as an example. The drift region 18 may be a region which has remained without other doping regions formed in the semiconductor substrate 10. That is, a doping concentration of the drift region 18 may be a doping concentration of the semiconductor substrate 10.

The buffer region 20 is a region provided below the drift region 18. The buffer region 20 of the present example is of the same conductivity type as that of the drift region 18, the N+ type as an example. A doping concentration of the buffer region 20 is higher than the doping concentration of the drift region 18. The buffer region 20 may function as a field stop layer for preventing a depletion layer, which spreads from the lower surface side of the base region 14, from reaching the collector region 22 and the cathode region 82.

The collector region 22 is a region which is provided below the buffer region 20 in the transistor portion 70 and which is of a conductivity type different from that of the drift region 18. The cathode region 82 is a region which is provided below the buffer region 20 in the diode portion 80 and which is of the same conductivity type as that of the drift region 18. A boundary between the collector region 22 and the cathode region 82 is a boundary between the transistor portion 70 and the diode portion 80.

The collector electrode 24 is provided on the back surface 23 of the semiconductor substrate 10. The collector electrode 24 is formed of a conductive material such as metal. The collector electrode 24 is an example of a back surface electrode. The collector electrode 24 of the present example includes nickel. The thickness of the collector electrode 24 of the present example may be equal to or greater than 1.0 μm and equal to or smaller than 2.0 μm.

The base region 14 is a region provided above the drift region 18 in the mesa portion, and having a conductivity type different from that of the drift region 18. The base region 14 of the present example is, for example, of the P-type. The base region 14 is provided in contact with the gate trench portion 40. The base region 14 may be provided in contact with the dummy trench portion 30.

The emitter region 12 is provided between the base region 14 and the front surface 21 of the semiconductor substrate 10. The emitter region 12 of the present example is provided in the mesa portion of the transistor portion 70 and not provided in the mesa portion of the diode portion 80. The emitter region 12 is provided in contact with the gate trench portion 40. The emitter region 12 may be or may not be in contact with the dummy trench portion 30.

Although not shown in FIG. 5, the contact region 15 and the emitter region 12 are alternately provided in the mesa portion of the transistor portion 70. The contact region 15 may be provided to a deeper position in the semiconductor substrate 10 than the emitter region 12.

The accumulation region 16 is a region provided closer to the front surface 21 side of the semiconductor substrate 10 than the drift region 18. The accumulation region 16 of the present example is of the same conductivity type as the that of the drift region 18, and is of N+ type, as an example. The accumulation region 16 of the present example is provided only in the transistor portion 70, and may also be provided in the diode portion 80. In addition, the accumulation region 16 may be provided with multiple stages.

The accumulation region 16 is provided in contact with the gate trench portion 40. The accumulation region 16 may or may not be in contact with the dummy trench portion 30. The doping concentration of the accumulation region 16 is higher than the doping concentration of the drift region 18. Providing the accumulation region 16 can increase a carrier injection enhancement effect (IE effect) to reduce an ON voltage of the transistor portion 70.

One or more gate trench portions 40 and one or more dummy trench portions 30 are provided in the front surface 21 of the semiconductor substrate 10. Each trench portion is provided from the front surface 21 of the semiconductor substrate 10 through the drift region 18. In a region provided with at least any of the emitter region 12, the base region 14, the contact region 15, and the accumulation region 16, each trench portion also penetrates through these regions to reach the drift region 18.

Note that a configuration in which a trench portion penetrates a doping region is not limited to a configuration that is manufactured by performing processes of forming a doping region and forming a trench portion in this order. The configuration of the trench portions penetrating the doping region also includes a configuration of forming the trench portions and then forming the doping region between the trench portions.

The gate trench portion 40 has a gate trench, a gate dielectric film 42, and a gate conductive portion 44 that are formed in the front surface 21 of the semiconductor substrate 10. The gate dielectric film 42 is provided to cover an inner wall of the gate trench. The gate dielectric film 42 may be formed by oxidizing or nitriding a semiconductor at the inner wall of the gate trench. The gate conductive portion 44 is provided inside the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21 of the semiconductor substrate 10.

The gate conductive portion 44 includes, in the depth direction (−Z axis direction) of the semiconductor substrate 10, a region opposing the adjacent base region 14 on the mesa portion side, having the gate dielectric film 42 therebetween. When a predetermined voltage is applied to the gate conductive portion 44, a channel is formed by an electron inversion layer in a surface layer of the base region 14 at a boundary in contact with the gate trench.

The dummy trench portion 30 may have the same structure as that of the gate trench portion 40. The dummy trench portion 30 includes a dummy trench, a dummy dielectric film 32, and the dummy conductive portion 34 that are formed in the front surface 21 side of the semiconductor substrate 10. The dummy dielectric film 32 is provided to cover an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided on the front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. The contact hole 54 and the contact hole 56 may be provided to penetrate the interlayer dielectric film 38.

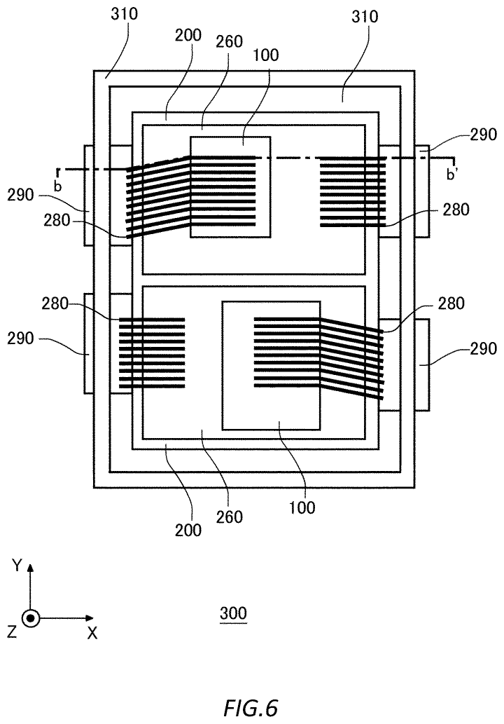

FIG. 6 is a top plan view showing an example of a semiconductor module 300 according to the example. The semiconductor module 300 of the present example includes a plurality of semiconductor devices 100, a resin casing 310, a dielectric substrate 200, a wiring pattern 260, a bonding wire 280, and a lead frame 290.

The resin casing 310 of the present example may be provided to surround a space accommodating the semiconductor device 100. The semiconductor device 100 may be the semiconductor device 100 shown in FIG. 1 to FIG. 5. The resin casing 310 of the present example may accommodate two semiconductor devices 100 having different sizes. A sealing resin 240 is provided above the semiconductor device 100, but is omitted in FIG. 6.

The resin casing 310 of the present example may be molded with a resin such as a thermosetting resin formable by injection molding, or an ultraviolet curing resin formable by UV molding. The resin may include, for example, one or more polymer materials selected from polyphenylene sulfide (PPS) resin, polybutylene terephthalate (PBT) resin, polyamide (PA) resin, acrylonitrile butadiene styrene (ABS) resin, acrylic resin, and the like.

The dielectric substrate 200 of the present example may be provided in the resin casing 310. The dielectric substrate 200 of the present example may be provided by stacking the resin dielectric layer 210 on the base substrate 215. The base substrate 215 is, for example, a copper sheet. A lower surface of the base substrate 215 may be provided with a cooler.

The semiconductor devices 100 are electrically connected to the electrical circuit provided inside the semiconductor module 300. The semiconductor device 100 of the present example is electrically connected to at least one of the wiring pattern 260 and the lead frame 290. In the example of FIG. 6, the front surface electrode of the semiconductor device 100 and the lead frame 290 are electrically connected via the bonding wire 280.

The wiring pattern 260 and the lead frame 290 are a part of an electrical circuitry. The wiring pattern 260 and the lead frame 290 may be electrically connected to each other. The electrical circuit provided in the semiconductor module 300 may include other electrical devices.

The wiring pattern 260 of the present example may be provided on an upper surface of the dielectric substrate 200. The wiring pattern 260 is, for example, a copper sheet or an aluminum sheet. The wiring pattern 260 of the present example may be configured by directly bonding a copper sheet or a plated aluminum sheet on the dielectric substrate 200 or by bonding a copper sheet or a plated aluminum sheet on the dielectric substrate 200 via a brazing material layer.

The semiconductor device 100 is provided on an upper surface of the wiring pattern 260 of the present example. A bonding portion such as soldering (not shown) may be provided between the semiconductor device 100 and the wiring pattern 260 of the present example. The semiconductor device 100 of the present example may be protected by the sealing resin 240 filling the resin casing 310. The sealing resin 240 is formed of, for example, a dielectric material such as silicon gel.

The lead frame 290 of the present example electrically connects the inside and the outside of the resin casing 310. The lead frame 290 of the present example may be formed of a conductive member such as copper. The lead frame 290 of the present example may be provided to protrude from a side wall of the resin casing 310 to the outside.

The semiconductor device 100 of the present example is connected to the wiring pattern 260 through the back surface electrode (the collector electrode 24) and connected to a plurality of bonding wires 280 through the front surface electrode (the emitter electrode 52).

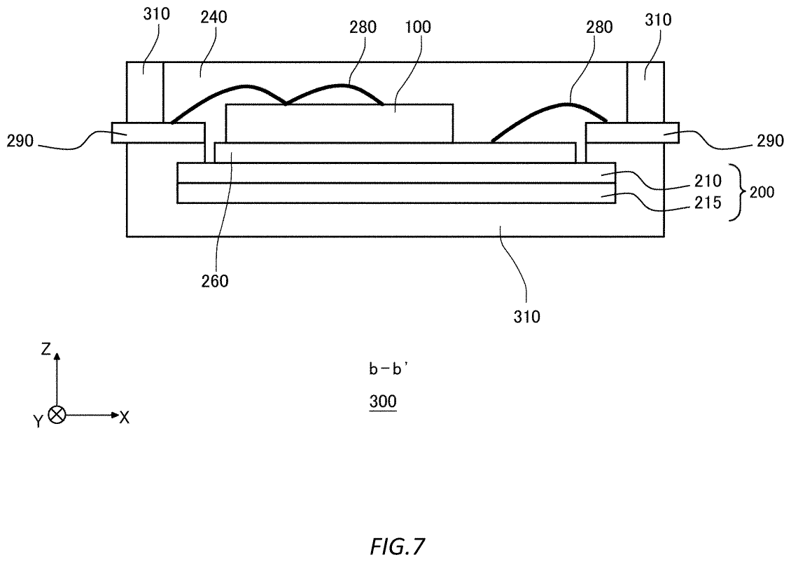

FIG. 7 shows an example of a b-b′ cross section of FIG. 6. The bonding wire 280 of the present example extends in the X axis direction and electrically connects the semiconductor device 100 and the lead frame 290. The bonding wire 280 of the present example is connected to the bonding region 50 on the upper surface of the emitter electrode 52 of the semiconductor device 100 (refer to FIG. 3 and the like). The bonding wire 280 may be bonded by crimping or may be fixed with a fixing member such as soldering on the upper surface of the emitter electrode 52. The bonding wire 280 connects at least two bonding regions 50.

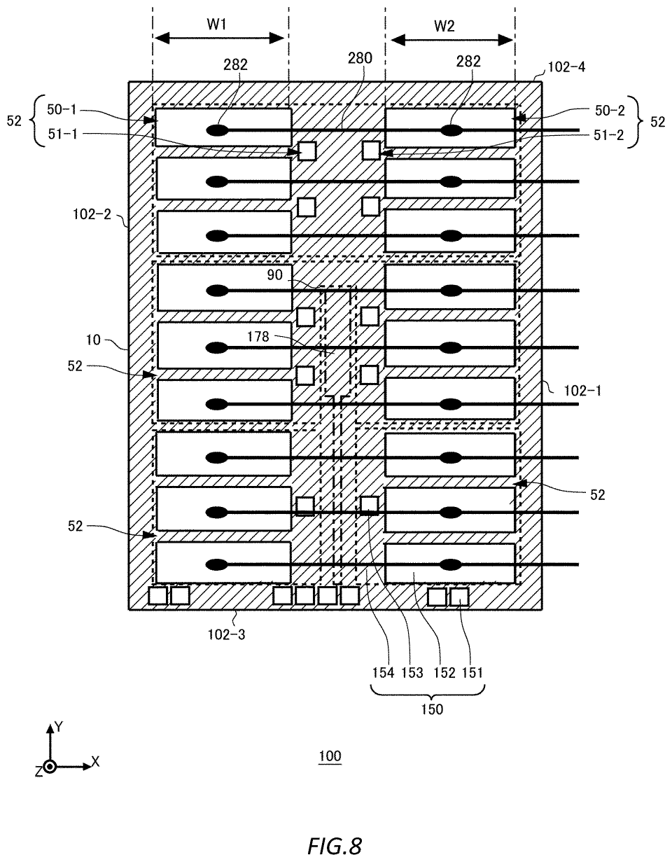

FIG. 8 shows an example of a top plan view of the semiconductor device 100. Similarly to FIG. 3, FIG. 8 shows an example of an arrangement of the protective film 150 provided on the front surface of the semiconductor device 100.

In FIG. 8, each bonding wire 280 electrically connects the first bonding region 50-1 and the second bonding region 50-2 opposed to each other in the X axis direction. The bonding wire 280 of the present example may be bonded or may be fixed with a fixing member such as soldering on the bonding region 50 by crimping. A fixing portion 282 which is a region of the bonding wire 280 fixed to the bonding region 50 is shown as a black oval shape in FIG. 8. The fixing portion 282 of the present example is spaced apart from the end portion of the bonding region 50 by equal to or greater than 50 μm.

In the example of FIG. 8, the bonding wire 280 is relayed at the fixing portion 282 in the second bonding region 50-2 and terminates at the fixing portion 282 in the first bonding region 50-1. In the X axis direction, the width W1 of the first bonding region 50-1 may be the same as the width W2 of the second bonding region 50-2. Therefore, in the present example, in a top view of the semiconductor substrate 10, an area of the first bonding region 50-1 may be the same as an area of the second bonding region 50-2.

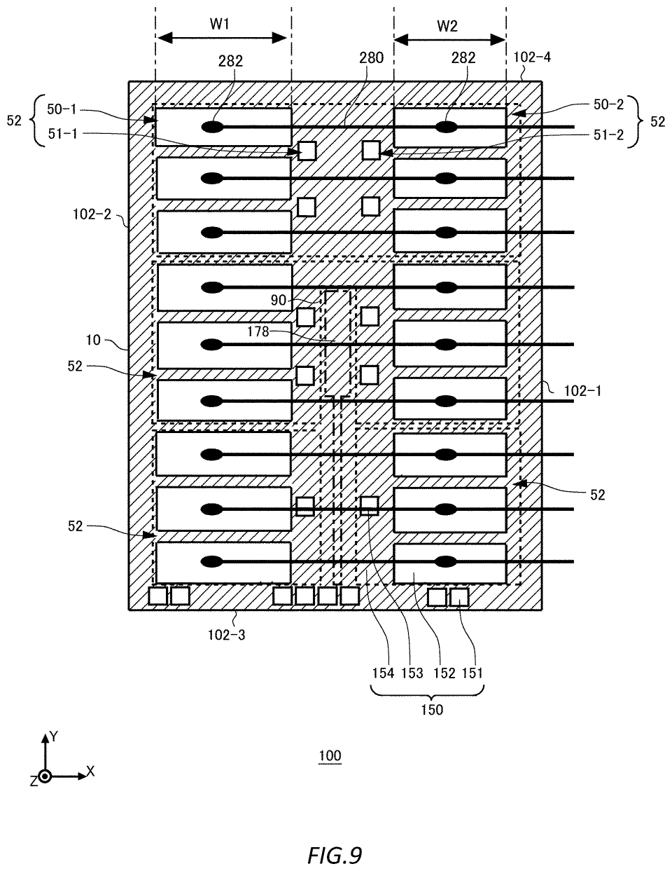

FIG. 9 shows another example of a top plan view of the semiconductor device 100. Here, the matter common with FIG. 8 will not be described and the difference will mainly be described.

An area of the first bonding region 50-1 of the present example may be different from an area of the second bonding region 50-2. In the X axis direction, the width W2 of the second bonding region 50-2 may be smaller than the width W1 of the first bonding region 50-1. Therefore, in the present example, in a top view of the semiconductor substrate 10, an area of the second bonding region 50-2 may be smaller than an area of the first bonding region 50-1.

In a top view of the semiconductor substrate 10, an area of the fixing portion 282 in the first bonding region 50-1 may be greater than an area of the fixing portion 282 in the second bonding region 50-2 so that the bonding wire 280 terminates. Therefore, in a top view of the semiconductor substrate 10, an area of the second bonding region 50-2 is decreased so that an opening portion ratio of the protective film 150 is decreased. This can increase an area ratio where the sealing resin 240 and the polyimide contact each other to prevent the sealing resin 240 from being detached.

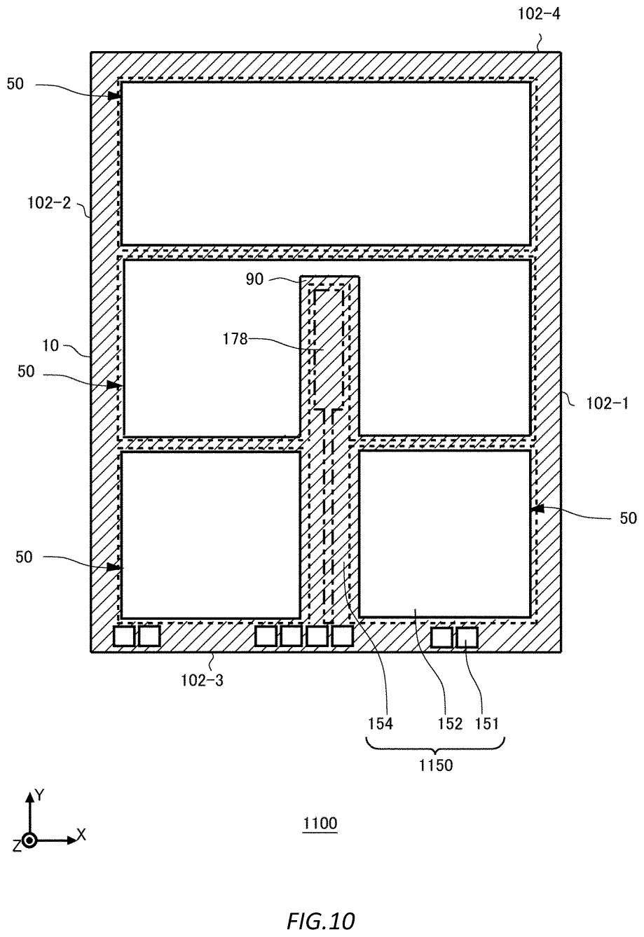

FIG. 10 shows an example of an arrangement of a protective film 1150 provided on a semiconductor device 1100 according to the comparative example. The protective film 1150 of the comparative example is different from the protective film 150 described in FIG. 3 in a higher opening portion ratio. Here, the matter common with FIG. 3 will not be described and the difference will mainly be described.

The protective film 1150 of the comparative example includes an opening portion 151 exposing a part of an upper surface of a pad in the pad region, an opening portion 152 exposing a part of an upper surface of the emitter electrode 52, and a not-opening portion 154. That is, the protective film 1150 of the comparative example is not provided with the opening portion 153 for exposing the testing region 51 in FIG. 3.

The semiconductor device 1100 according to the comparative example is not provided with the testing region 51 so that a probe or the like is connected to the bonding region 50 on the upper surface of the emitter electrode 52 in the wafer test. An imprint of the probe formed in the wafer test remains on the upper surface of the emitter electrode 52, which may further cause a detachment of the sealing resin of the semiconductor module.

In addition, in the semiconductor device 1100 according to the comparative example, while the not-opening portion 154 is provided above the gate runner portion 48 extending between the active portions 120 in the X axis direction, it is not provided to extend above the active portion 120. Therefore, the opening portion ratio of the protective film 1150 of the comparative example is higher than the opening portion ratio of the protective film 150 in FIG. 3, which results in a smaller area ratio where the sealing resin and the polyimide of the semiconductor module contact each other so that a detachment of the sealing resin of the semiconductor module tends to occur.

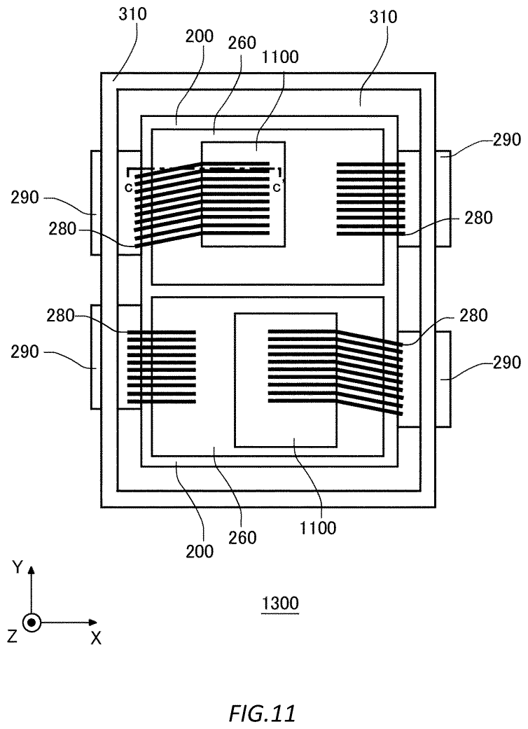

FIG. 11 shows an example of a top plan view of a semiconductor module 1300 according to the comparative example. The semiconductor module 1300 according to the comparative example is different from the semiconductor module 300 shown in FIG. 6 in the semiconductor device 1100 shown in FIG. 10 and the same in other configurations.

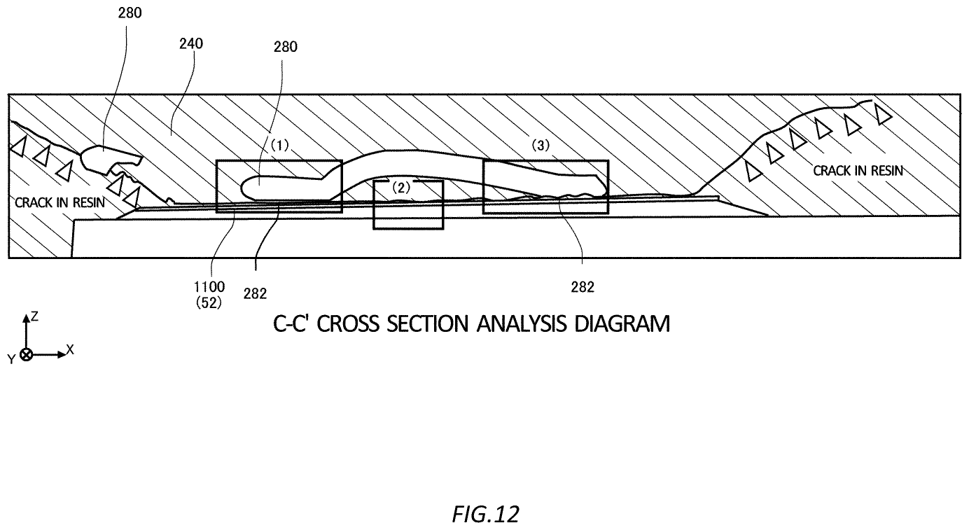

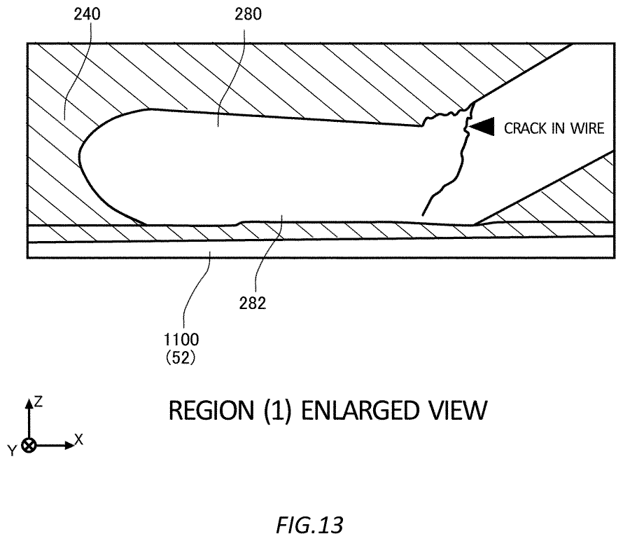

FIG. 12 is a cross section analysis diagram of the semiconductor module 1300 when a crack occurs in the bonding wire and the sealing resin. FIG. 13 shows a Focused Ion Beam analysis (FIB-SEM) image in which a region (1) on a c-c′ cross section of FIG. 12 is enlarged. In FIG. 12, the bonding wire 280 extends from the negative side to the positive side in the X axis direction, and is fixed to the front surface of the semiconductor device 100 at two fixing portions 282.

A reliability test was performed for the semiconductor module 1300. The reliability test is a test for measuring a product defect rate by generating a current to flow in the semiconductor module for repeating cycles of an increase and decrease in the bonding temperature. As a result of the reliability test, a detachment or crack of the sealing resin 240 occurs in regions (1) to (3) shown in FIG. 12.

The region (1) is in the vicinity of the fixing portion 282 at the outer circumference side (the negative side in the X axis direction) of the semiconductor module 1300. Here, the detachment occurs between the sealing resin 240 and the semiconductor device 1100 (the upper surface of the emitter electrode 52). An end portion of the bonding wire 280 in the region (1) is connected to the lead frame 290 in the Z axis direction.

The region (2) is a region between the fixing portions 282 where the bonding wire 280 is spaced apart from the semiconductor device 1100. Here, the bonding wire 280 is spaced apart from the semiconductor device 1100 (the upper surface of the emitter electrode 52) so that a heat load or a mechanical load is difficult to be applied. Therefore, the detachment does not occur between the semiconductor device 1100 (the upper surface of the emitter electrode 52) and the sealing resin 240.

The region (3) is in the vicinity of the fixing portion 282 at the inner side (the positive side in the X axis direction) of the semiconductor module 1300. Here, the detachment occurs between the sealing resin 240 and the semiconductor device 1100 (the upper surface of the emitter electrode 52). The bonding wire 280 in the region (3) is a terminating portion of the bonding wire 280.

The detachment occurring in the regions (1) and (3) displaces the bonding wire 280 so that a crack occurred in the sealing resin 240 (a white triangle in the c-c′ cross section analysis diagram of FIG. 12). In addition, the crack results in an increase in the bonding area of the bonding wire 280 and an increase in a resistance at a bonding location, thereby increasing an amount of heat generation. Therefore, the crack occurred in the bonding wire 280 in the region (1) (a black triangle in the enlarged view of the region (1) in FIG. 13).

In the semiconductor module 300 according to the example, the emitter electrode 52 of the semiconductor device 100 includes the testing region 51 provided separately aside from the bonding region 50, where an area of the testing region 51 is smaller than an area of the bonding region 50. Therefore, in the bonding region 50, the sealing resin 240 of the semiconductor module 300 can be prevented from being detached from the upper surface of the emitter electrode.

In the semiconductor module 300 according to the example, the testing region 51 of the semiconductor device 100 is provided in the center portion of the semiconductor substrate 10, but not provided in the pad region. Therefore, an opening portion ratio is not increased in the peripheral region. This prevents a decrease in an area ratio where the sealing resin contacts the polyimide in the peripheral region of the semiconductor module 300 so that the sealing resin 240 of the semiconductor module 300 can be prevented from being detached.

While the embodiments of the present invention have been described, the technical scope of the invention is not limited to the above described embodiments. It is apparent to persons skilled in the art that various alterations and improvements can be added to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as “first” or “next” for the sake of convenience in the claims, specification, and drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 20: buffer region, 21: front surface, 22: collector region, 23: back surface, 24: collector electrode, 25: connection portion, 29: extending portion, 30: dummy trench portion, 31: connecting portion, 32: dummy dielectric film, 34: dummy conductive portion, 38: interlayer dielectric film, 39: extending portion, 40: gate trench portion, 41: connecting portion, 42: gate dielectric film, 44: gate conductive portion, 48: gate runner portion, 50: bonding region, 51: testing region, 52: emitter electrode, 54: contact hole, 56: contact hole, 70: transistor portion, 80: diode portion, 82: cathode region, 90: separating portion, 100: semiconductor device, 102: end side, 120: active portion, 130: edge termination structure, 150: protective film, 151: opening portion, 152: opening portion, 153: opening portion, 154: not-opening portion, 170: gate pad, 171: testing pad, 172: current sensing pad, 173: testing pad, 174: anode pad, 175: testing pad, 176: cathode pad, 177: testing pad, 178: temperature sensing portion, 180: cathode wiring, 182: anode wiring, 200: dielectric substrate, 210: dielectric layer, 215: base substrate, 240: sealing resin, 260: wiring pattern, 280: bonding wire, 282: fixing portion, 290: lead frame, 300: semiconductor module, 310: resin casing, 1100: semiconductor device, 1150: protective film, 1300: semiconductor module

What is claimed is:

1. A semiconductor device, comprising:
a protective film provided above a front surface of a semiconductor substrate; and
a front surface electrode provided above the front surface of the semiconductor substrate; wherein
the front surface electrode includes:
a plurality of bonding regions exposed through a plurality of opening portions provided in the protective film; and
a plurality of testing regions for testing, and wherein
in a top view of the semiconductor substrate, an area of each testing region is smaller than an area of each bonding region.

2. The semiconductor device according to claim 1, wherein
in a top view of the semiconductor substrate, the plurality of testing regions are arranged along a predetermined first direction in a center portion of the semiconductor substrate.

3. The semiconductor device according to claim 2, wherein
the plurality of bonding regions include a first bonding region group and a second bonding region group arrayed in the first direction, and
the plurality of testing regions are arrayed between the first bonding region group and the second bonding region group.

4. The semiconductor device according to claim 3, wherein
the first direction is a longitudinal direction of the semiconductor substrate.

5. The semiconductor device according to claim 3, wherein
the protective film includes a not-opening portion between the first bonding region group and the second bonding region group, and at least a portion of the not-opening portion is provided above the front surface electrode.

6. The semiconductor device according to claim 3, comprising:
a plurality of gate trench portions provided on the front surface of the semiconductor substrate; and
a gate runner portion electrically connected to the plurality of gate trench portions and provided to extend between the plurality of bonding regions in a second direction different from the first direction.

7. The semiconductor device according to claim 2, comprising:
a temperature sensing portion arranged in the center portion of the semiconductor substrate.

8. The semiconductor device according to claim 7, wherein
in a top view of the semiconductor substrate, the temperature sensing portion is provided between the plurality of testing regions.

9. The semiconductor device according to claim 7, wherein
the plurality of testing regions include a first testing region group and a second testing region group arrayed in the first direction, and
in a top view of the semiconductor substrate, the temperature sensing portion is provided between the first testing region group and the second testing region group.

10. The semiconductor device according to claim 1, wherein
the plurality of bonding regions include a first bonding region and a second bonding region connected to the first bonding region with a bonding wire, and
the protective film includes, in a top view of the semiconductor substrate, a not-opening portion provided between the first bonding region and the second bonding region.

11. The semiconductor device according to claim 10, wherein
in a top view of the semiconductor substrate, an area of the first bonding region is different from an area of the second bonding region.

12. The semiconductor device according to claim 1, comprising:
a back surface electrode provided on a back surface of the semiconductor substrate and including nickel.

13. The semiconductor device according to claim 12, wherein
a thickness of the back surface electrode is equal to or greater than 1.0 μm and equal to or smaller than 2.0 μm.

14. A semiconductor module comprising the semiconductor device according to claim 1.

15. A semiconductor module comprising the semiconductor device according to claim 2.

16. A semiconductor module comprising the semiconductor device according to claim 3.

17. A semiconductor module comprising the semiconductor device according to claim 4.

18. The semiconductor module according to claim 14, comprising:
a bonding wire connecting at least two bonding regions among the plurality of bonding regions.

19. The semiconductor module according to claim 18, wherein
in a top view of the semiconductor substrate, an area of a bonding region relaying the bonding wire is smaller than an area of a bonding region in which the bonding wire terminates.

20. The semiconductor module according to claim 14, comprising:
a sealing resin provided above the semiconductor device.
